(19) United States
(12) Patent Application Publication
(10) Pub. No.: US 2015/0210532 A1
(43) Pub. Date: Jul. 30, 2015

(54) MEMS GAS SENSING DEVICE

(71) Applicant: SENSOR TEK Co., Ltd., Taipei City (TW)

(72) Inventors: Mao-Chen LIU, Jiji Township (TW); Hao-Ming CHAO, Taipei City (TW); Wen-Chieh CHOU, Guishan Township (TW); Po-Wei LU, Bade City (TW); Shu-Yi WENG, Zhunan Township (TW); Chun-Chieh WANG, Taichung City (TW)

(21) Appl. No.: 14/608,982

(22) Filed: Jan. 29, 2015

(30) Foreign Application Priority Data
Jan. 29, 2014 (TW) 103103507

(51) Int. Cl. B81B 1/00; B81B 7/00

(52) U.S. Cl. CPC B81B 1/002; B81B 7/0083; B81B 2201/0214

(57) ABSTRACT

A microelectromechanical system (MEMS) gas sensing device includes a substrate, an oxide layer, a heating unit, a thermal-conductive metal layer, a passivation layer, and a sensor layer. The substrate includes a first cavity. The oxide layer has a first surface and a second surface opposite to the first surface, is on the substrate, and covers on the first cavity. The first surface contacts the substrate. The heating unit is in the oxide layer and adjacent to the first surface of the oxide layer. The thermal-conductive metal layer is between the heating unit and the second surface of the oxide layer. The passivation layer is on the second surface of the oxide layer and includes at least one via. The sensor layer is on the passivation layer and electrically connected to the thermal-conductive metal layer through the at least one via.

### CROSS-REFERENCE TO RELATED APPLICATIONS

This non-provisional application claims priority under 35 U.S.C. §119(a) on Patent Application No(s). 103103507 filed in Taiwan, R.O.C. on Jan. 29, 2014, the entire contents of which are hereby incorporated by reference.

### TECHNICAL FIELD

The disclosure relates to a gas sensing device, more particularly to a microelectromechanical system (MEMS) gas sensing device.

### BACKGROUND

Gas detection is widely applied to environment monitoring, household alarms, chemical industry control, and greenhouse environment control. Some poisonous gases or toxic gases, e.g. carbon monoxide (CO), are invisible and odorless, making it very difficult for people to detect. Toxic gas poisoning occurs after too much inhalation of a toxic gas. The symptoms of toxic gas poisoning range from a headache, nausea and syncope to a coma, weak pulse, respiratory failure, or even death. Therefore, gas analysis equipment is promoted to monitor the constituents of air in a confined space or semi-confined space in real time. When the concentration of toxic gas exceeds a safe exposure limit to a human being, such gas analysis equipment gives an alarm in real time to avoid the occurrence of a possible disaster.

Although gas analysis equipment in common chemical laboratories and quality control laboratories have high accuracy, high sensitivity, and a low detection limit, such equipment is big and not easy to carry, consumes more power, and has a complicated structure and a high cost, resulting in the limitation of its application.

### SUMMARY

According to one embodiment, the disclosure provides a MEMS gas sensing device including a substrate, an oxide layer, a heating unit, a thermal-conductive metal layer, a passivation layer, and a sensor layer. The substrate includes a first cavity. The oxide layer has a first surface and a second surface opposite to the first surface. The oxide layer is on the substrate and covers the first cavity, and the first surface of the oxide layer contacts the substrate. The heating unit is in the oxide layer and adjacent to the first surface of the oxide layer. The thermal-conductive metal layer is between the heating unit and the second surface of the oxide layer. The passivation layer is on the second surface of the oxide layer and includes at least one via. The sensor layer is on the passivation layer and is electrically connected to the thermal-conductive metal layer through the at least one via.

In other one embodiment, the oxide layer further includes a second cavity and a third cavity, and the second cavity and the third cavity are respectively at two opposite sides of the thermal-conductive metal layer.

In other one embodiment, the second cavity and the third cavity are formed by an inductively coupled plasma etching.

In another embodiment, the heating unit is made of polysilicon.

In another embodiment, the thermal-conductive metal layer includes a first metal layer adjacent to the heating unit, a first contact layer on the first metal layer, a second metal layer on the first contact layer, a second contact layer on the second metal layer, a third metal layer on the second contact layer, a third contact layer on the third metal layer, a fourth metal layer on the third contact layer, a fourth contact layer on the fourth metal layer, a fifth metal layer on the fourth contact layer, a fifth contact layer on the fifth metal layer, and a sixth metal layer on the fifth contact layer. The sixth metal layer is electrically connected to the sensor layer through the at least one via.

In another embodiment, the first metal layer, the second metal layer, the third metal layer, the fourth metal layer, the fifth metal layer, and the sixth metal layer are made of aluminium, and the first contact layer, the second contact layer, the third contact layer, the fourth contact layer, and the fifth contact layer are made of tungsten.

In another embodiment, the sensor layer is made of gold, aluminium, silver, platinum. copper, titanium, molybdenum, tantalum, tungsten, or chromium.

In another embodiment, a temperature to form the sensor layer is in a range of 400° C. to 450□.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a schematic diagram of a MEMS gas sensing device in an embodiment; and

FIG. 2 is a schematic diagram of a MEMS gas sensing device in another embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings. Every following embodiment uses the same label to represent the same elements or similar elements.

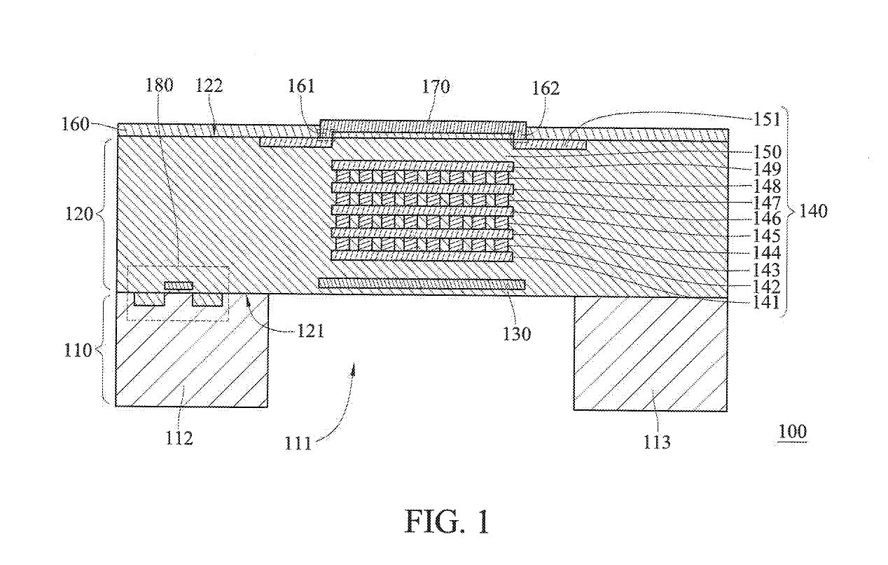

FIG. 1 is a schematic diagram of a MEMS gas sensing device in an embodiment. A MEMS gas sensing device 100 includes a substrate 110, an oxide layer 120, a heating unit 130, a thermal-conductive metal layer 140, a passivation layer 160, a sensor layer 170, and a circuit component 180.

The substrate 110 includes a first cavity 111. The first cavity 111 can be formed by a semiconductor fabrication process, e.g. the dry etching. After the first cavity is formed, the substrate 110 is divided by the first cavity 111 into sub substrates 112 and 113. In other words, the first cavity 111 is between the sub substrates 112 and 113.

The oxide layer 120 has a first surface 121 and a second surface 122 opposite to the first surface 121. The oxide layer 120 is on the substrate 110 and covers on the first cavity 111. The first surface 121 of the oxide layer 120 contacts the substrate 110, that is, the first surface 121 of the oxide layer 120 contacts the sub substrates 112 and 113.

The heating unit 130 is in the oxide layer 120 and adjacent to the first surface 121 of the oxide layer 120. The location of the heating unit 130 corresponds to the location of the first cavity 111. The heating unit 130 is adjacent to and is on the first cavity 111.

The thermal-conductive metal layer 140 is between the heating unit 130 and the second surface 122 of the oxide layer 120. The thermal-conductive metal layer 140 includes a first metal layer 141, a first contact layer 142, a second metal layer 143, a second contact layer 144, a third metal layer 145, a third contact layer 146, a fourth metal layer 147, a fourth contact layer 148, a fifth metal layer 149, a fifth contact layer 150, and a sixth metal layer 151.

The thermal-conductive metal layer 140 is formed by depositing and piling the first metal layer 141, the first contact layer 142, the second metal layer 143, the second contact layer 144, the third metal layer 145, the third contact layer 146, the fourth metal layer 147, the fourth contact layer 148, the fifth metal layer 149, the fifth contact layer 150, and the sixth metal layer 151 on the top of each other. The first metal layer 141 is adjacent to the heating unit 130. The first contact layer 142 is on the first metal layer 141. The second metal layer 143 is on the first contact layer 142. The second contact layer 144 is on the second metal layer 143. The third metal layer 145 is on the second contact layer 144. The third contact layer 146 is on the third metal layer 145. The fourth metal layer 147 is on the third contact layer 146. The fourth contact layer 148 is on the fourth metal layer 147. The fifth metal layer 149 is on the fourth contact layer 148. The fifth contact layer 150 is on the fifth metal layer 149. The sixth metal layer 151 is on the fifth contact layer 150. In this or some embodiments, the first metal layer 141, the second metal layer 143, the third metal layer 145, the fourth metal layer 147, the fifth metal layer 149, and the sixth metal layer 151 are made of aluminium (Al), but the disclosure will not be limited thereto. In this or some embodiments, the first contact layer 142, the second contact layer 144, the third contact layer 146, the fourth contact layer 148, and the fifth contact layer 150 are made of tungsten (W), but the disclosure will not be limited thereto.

The passivation layer 160 is on the second surface 122 of the oxide layer 120 and includes two vias 161 and 162. The sensor layer 170 is on the passivation layer 160, and the sensor layer 170 is electrically connected to the thermal-conductive metal layer 140 through the vias 161 and 162. For example, the sensor layer 170 is electrically connected to the sixth metal layer 151 of the thermal-conductive metal layer 140 through the vias 161 and 162. The circuit component 180 is between the sub substrate 112 and the oxide layer 120.

In this or some embodiments, the heating unit 130 is made of polysilicon, but the disclosure will not be limited thereto. The heating unit 130 includes a heater and a thermometer. The heater in the heating unit 130 may increase the probability that charge carriers are excited across the energy band gap from the valence band to the electrical conduction band. The thermometer of the heating unit 130 senses the temperature of the heat produced by the heater.

For example, the sensor layer 170 is made of gold (Au), aluminium (Al), silver (Ag), platinum (Pt), copper (Cu), titanium (Ti), molybdenum (Mo), tantalum (Ta), tungsten (W), or chromium (Cr), but the disclosure will not be limited thereto. The sensor layer 170 is shaped by, for example, a photomask and a deposition process. For instance, the temperature to form the sensor layer 170 is in a range of 400 to 450□ for the metal oxidization process. In this or some embodiments, the sensor layer 170 senses a specific gas, e.g. carbon monoxide (CO).

Accordingly, the thermal-conductive metal layer 140 conducts the heat produced by the heating unit 130 to the sensor layer 170 in order to uniformly heat the sensor layer 170. The thermal-conductive metal layer 140 separates the heating unit 130 from the sensor layer 170, so that the MEMS gas sensing device 100 may be integrated and have the ability of batch production.

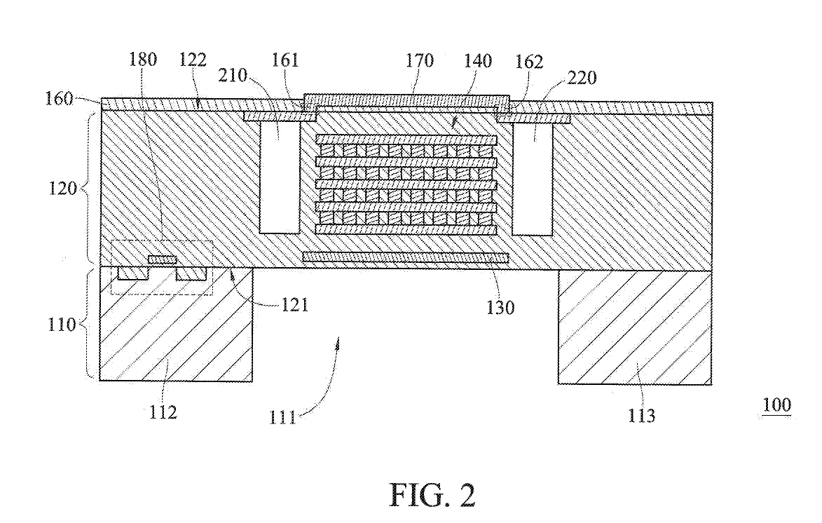

FIG. 2 is a schematic diagram of a MEMS gas sensing device in another embodiment. A MEMS gas sensing device 200 includes not only the substrate 110, the oxide layer 120, the heating unit 130, the thermal-conductive metal layer 140, the passivation layer 160, the sensor layer 170, and the circuit component 180 aforementioned but also a second cavity 210 and a third cavity 220.

The second cavity 210 and the third cavity 220 are respectively at two opposite sides of the thermal-conductive metal layer 140. For example, the second cavity 210 and the third cavity 220 are formed by a semiconductor fabrication process, e.g. the inductively coupled plasma (ICP) etching. Since the second cavity 210 and the third cavity 220 are respectively at the two opposite sides of the thermal-conductive metal layer 140, the heat produced by the heating unit 130 may efficiently be confined to the space among the heating unit 130, the sensor layer 170, the second cavity 210, and the third cavity 220 and may be protected from being defused to other parts of the oxide layer 120 and then affecting the operation of the circuit component 180.

For the MEMS gas sensing device in the disclosure, the thermal-conductive metal layer between the heating unit and the sensor layer may make the heat produced by the heating unit warm up the sensor layer. Since the thermal-conductive metal layer separates the heating unit from the sensor layer, the MEMS gas sensing device may be integrated and have the capability of batch production. Moreover, the second and third cavities at the two opposite sides of the thermal-conductive metal layer may efficiently confine the heat produced by the heating unit to the space among the heating unit, the sensor layer, and the second and third cavities so that the heat produced by the heating unit is protected from being defused to other parts of the oxide layer and then affecting the operation of the circuit component.

What is claimed is:

1. A microelectromechanical system (MEMS) gas sensing device, comprising:
a substrate including a first cavity;
an oxide layer having a first surface and a second surface opposite to the first surface, the oxide layer being on the substrate and covering on the first cavity, and the first surface contacting the substrate;
a heating unit being in the oxide layer and adjacent to the first surface of the oxide layer;
a thermal-conductive metal layer being between the heating unit and the second surface of the oxide layer;
a passivation layer being on the second surface of the oxide layer and comprising at least one via; and
a sensor layer being on the passivation layer and being electrically connected to the thermal-conductive metal layer through the at least one via.

2. The MEMS gas sensing device according to claim 1, wherein the oxide layer further comprises a second cavity and a third cavity, and the second cavity and the third cavity are at two opposite sides of the thermal-conductive metal layer respectively.

3. The MEMS gas sensing device according to claim 2, wherein the second cavity and the third cavity are formed by an inductively coupled plasma etching.

4. The MEMS gas sensing device according to claim 1, wherein the heating unit is made of polysilicon.

5. The MEMS gas sensing device according to claim 1, wherein the thermal-conductive metal layer comprises:
a first metal layer adjacent to the heating unit;
a first contact layer on the first metal layer;
a second metal layer on the first contact layer;
a second contact layer on the second metal layer;
a third metal layer on the second contact layer;
a third contact layer on the third metal layer;
a fourth metal layer on the third contact layer;
a fourth contact layer on the fourth metal layer;
a fifth metal layer on the fourth contact layer;
a fifth contact layer on the fifth metal layer; and
a sixth metal layer being on the fifth contact layer and electrically connected to the sensor layer through the at least one via.

6. The MEMS gas sensing device according to claim 5, wherein the first metal layer, the second metal layer, the third metal layer, the fourth metal layer, the fifth metal layer, and the sixth metal layer are made of aluminium (Al), and the first contact layer, the second contact layer, the third contact layer, the fourth contact layer, and the fifth contact layer are made of tungsten.

7. The MEMS gas sensing device according to claim 1, wherein the sensor layer is made of gold (Au), Al, silver (Ag), platinum (Pt), copper (Cu), titanium (Ti), molybdenum (Mo), tantalum (Ta), tungsten (W) or chromium (Cr).

8. The MEMS gas sensing device according to claim 1, wherein a temperature to form the sensor layer is in a range of 400° C. to 450° C.
